(19) United States
(12) Patent Application Publication
(10) Pub. No.: US 2009/0291532 A1
(43) Pub. Date: Nov. 26, 2009

(54) METHOD OF RESIN ENCAPSULATION MOLDING FOR ELECTRONIC PART

(76) Inventors: Shinji Takase, Kyoto (JP); Yohei Onishi, Kyoto (JP)

Correspondence Address: BIRCH STEWART KOLASCH & BIRCH, PO BOX 747, FALLS CHURCH, VA, 22040-0747, US

(21) Appl. No.: 12/096,568

(22) PCT Filed: Apr. 13, 2007
(86) PCT No.: PCT/JP2007/058150

§ 371 Date: Jun. 6, 2008

(30) Foreign Application Priority Data
May 17, 2006 (JP) 2006-138022

(51) Int. Cl. H01L 21/56

(52) U.S. Cl. 438/127; 257/E21.504

(57) ABSTRACT

A resin encapsulation molding apparatus comprises die assembly of triple die structure and mold release film for covering two cavities respectively corresponding to two substrates. Each of the two cavities comprises inferior die cavity face, cavity side face and cavity face consisting of communication channel face. The mold release film in the state of being tensioned covers each of the two cavities along the morphology thereof. In this condition, molten resin is injected into the two cavities. The molten resin is evenly distributed into the two cavities through communication channel communicating the two cavities with each other. Thereafter, the multiple electronic parts on the two substrates are almost simultaneously immersed in the molten resin within the two cavities and are compression molded.

### TECHNICAL FIELD

The present invention relates to a method of resin encapsulation molding for electronic parts, resin-encapsulating a plurality of electronic parts mounted on a substrate by compression molding.

### BACKGROUND ART

In recent years, size increase of a substrate has strongly been demanded for reduction in cost, regardless of the type of the substrate as well as performance/nonperformance of bonding and the method thereof. In recent years, further, the thickness of the substrate has been reduced, and the number of electronic parts such as ICs (Integration Circuits) such as semiconductor chips loaded on the substrate, for example, has been increased. In addition, a package formed by stacking semiconductor chips has been employed. Further, the package has been reduced in thickness. Further, the wire length of the semiconductor chip has been increased, and the wire interval has been reduced. Under the aforementioned circumstances, a method of collectively encapsulating a plurality of chips provided on a large and thin substrate with resin is demanded.

Therefore, a compression molding die assembly of a double die structure formed by an upper die and a lower die, for example, is employed. Further, a strip-shaped lead frame is employed as a substrate (pp. 3 to 5 and FIGS. 5 and 6 of Japanese Patent Laying-Open No. 2004-230707, for example).

In a conventional method of resin encapsulation molding, a prescribed quantity of resin material is supplied into a cavity formed in a lower die, and a substrate is thereafter set in the cavity formed in the lower die while semiconductor chips loaded on the substrate are directed downward, as disclosed in Japanese Patent Laying-Open No. 2004-230707. In this state, an upper die and the lower die are closed. Further, the resin material is supplied into the cavity. Thereafter the resin material is molten by heating. Consequently, the space in the cavity is filled up with the molten resin.

The aforementioned resin encapsulation molding apparatus comprises a sliding member mounted on the lower die, a closing mechanism vertically moving the sliding member for closing and opening the upper die and the lower die and clamp means upwardly moving the sliding member provided independently of the closing mechanism. Substantially simultaneously with the upward movement of the sliding member, the resin material (molten resin) supplied to the upper face of the sliding member also moves upward. Thus, the molten resin is supplied into the cavity. In the cavity, the plurality of semiconductor chips are covered with the molten resin. Consequently, the resin material in the cavity is encapsulated by the resin.

The inventors have studied whether or not a plurality of semiconductor chips provided on two substrates can be efficiently encapsulation-molded with resin in a single resin encapsulation step with one die assembly (upper and lower dies). Consequently, it has been recognized possible to implement this when changing the structure of the conventional resin encapsulation molding apparatus.

More specifically, an apparatus comprising a die assembly (upper and lower dies) capable of independently and substantially simultaneously resin-encapsulating two substrates by compression molding has been developed. When this apparatus is used, a prescribed quantity of resin material is first supplied into each of two cavities formed in the lower die. The substrates are set in recesses of the upper die. Thereafter the upper and lower dies are closed while chip mounting faces of the two substrates are directed downward. At this time, the resin material is molten by heating in each of the two cavities. Consequently, molten resin is formed in each of the two cavities.

Thereafter two clamp means move two sliding members upward. At this time, the molten resin has already been supplied to the upper face of each of the two sliding members. Therefore, the molten resin upwardly moves substantially simultaneously with the upward movement of the sliding members. Thus, the molten resin is supplied into the two cavities. Further, a plurality of semiconductor chips are dipped in the molten resin. In other words, compression molding is executed. Thereafter the resin material in the two cavities is cured. Thus, resin encapsulation of the plurality of semiconductor chips is completed.

### Patent Document 1: Japanese Patent Laying-Open No. 2004-230707 (pp. 3 to 5, FIGS. 5 and 6)

### DISCLOSURE OF THE INVENTION

### Problems to be Solved by the Invention

In a case of independently and substantially simultaneously resin-encapsulating respective electronic parts provided on two substrates (including lead frames) by compression molding with the aforementioned apparatus, the clamp means moving the two sliding members provided on the lower die upward and downward are necessary. The clamp means comprise driving sources such as motors and cylinders. Further, two clamp means corresponding to the two sliding members are necessary. Therefore, a large space is necessary for the closing mechanism moving the upper and lower dies upward and downward and the driving sources. Consequently, the overall structure of the resin encapsulation molding apparatus is increased in size.

In order to resin-encapsulate the substrates by compression molding, it is necessary to independently control the two sliding members with the clamp means until the pressure of the molten resin reaches a proper prescribed value after the upper and lower dies are closed. Therefore, it follows that a long time is consumed for the resin encapsulation step. Consequently, there arises such a problem that it is difficult to sufficiently improve the productivity of the resin encapsulation step.

Further, it is strongly demanded to correctly supply the prescribed quantity of resin material into the two cavities. However, it is difficult to uniformly distribute the prescribed quantity of resin material in the two cavities.

The present invention has been proposed in consideration of the aforementioned problems, and an object thereof is to provide a method of resin encapsulation molding capable of downsizing a resin encapsulation molding apparatus and uniformly distributing a prescribed quantity of resin material into two cavities in a case of compression-molding a plurality of electronic parts mounted on two substrates with one die assembly.

### Means for Solving the Problems

In the method of resin encapsulation molding for electronic parts according to the present invention, an upper die, a lower die opposed to the upper die and provided with cavities, an intermediate die provided between the upper die and the lower die and a mold release film are first prepared. Then, a plurality of substrates mounted with a plurality of electronic parts are mounted on the upper die. The mold release film is brought into close contact with the plurality of cavities by the intermediate die and the lower die. Thereafter the upper die, the intermediate die and the lower die are closed while the plurality of cavities are covered with the mold release film. Then, molten resin is formed in the plurality of cavities, or liquid resin or molten resin is injected into the plurality of cavities. The plurality of electronic parts are substantially simultaneously dipped in the liquid resin or the molten resin so that the liquid resin or the molten resin is uniformly distributed in the plurality of cavities through a communication channel making the plurality of cavities communicate with each other.

According to the aforementioned method, a resin encapsulation molding apparatus can be downsized while a prescribed quantity of resin material can be uniformly distributed into two cavities in a case of compression-molding a plurality of electronic parts mounted on two substrates with one die assembly.

The cavities may include lower die cavity faces serving as the bottom faces thereof and cavity side faces adjacent to the cavity faces, and the cavity side faces and the lower die cavity faces may be separable. According to this, cleaning of members constituting the cavities is simplified.

In the step of mounting the plurality of substrates, the plurality of substrates are mounted on the upper die while the plurality of substrates are adjacent to each other. According to this, the length of the communication channel can be reduced.

In the aforementioned closing step, the clearance between the upper die and the intermediate die may be sealed with a seal member for cutting off the outside air. In this case, the method of resin encapsulation may further comprise the step of evacuating the spaces in the cavities after the aforementioned closing step. According to this, formation of voids in the molten resin can be suppressed.

### EFFECTS OF THE INVENTION

According to the aforementioned method of resin encapsulation molding, a resin encapsulation molding apparatus can be downsized and a prescribed quantity of resin can be uniformly distributed into two cavities in a case of compression-molding a plurality of electronic parts mounted on two substrates with one die assembly.

The aforementioned and other objects, features, aspects and advantages of the present invention will become apparent from the following detailed description of the present invention understood in relation to the accompanying drawings.

### BRIEF DESCRIPTION OF THE DRAWINGS

FIG. 1 is a plan view of substrates loaded with electronic parts encapsulation-molded with a die assembly.

FIG. 2 is another exemplary plan view of substrates loaded with electronic parts encapsulation-molded with a die assembly.

FIG. 3 is still another exemplary plan view of substrates loaded with electronic parts encapsulation-molded with a die assembly.

FIG. 4 is a sectional view of a die assembly for resin-encapsulation-molding the electronic parts loaded on the substrates shown in each of FIGS. 1 to 3, showing an open state thereof.

FIG. 5 is a sectional view of the die assembly for resin-encapsulation-molding the electronic parts loaded on the substrates shown in each of FIGS. 1 to 3, showing a state where the substrates and a resin material are supplied thereto.

FIG. 6 is a perspective view of a lower die and an intermediate die.

FIG. 7 is a sectional view of the die assembly shown in FIG. 4, showing a state where the die assembly clamps the substrates shown in FIG. 1.

FIG. 8 is a sectional view of a die assembly, showing a state where another exemplary die assembly clamps the substrates.

### DESCRIPTION OF THE REFERENCE SIGNS

1 substrate, 2 electronic part (chip), 3 unencapsulated substrate, 4 resin material, 5 molten resin, 6 encapsulation-molded portion, 7 substrate periphery, 8 non-mounted face, 9 cured resin, 10 encapsulated substrate (product), 11 cured resin, 12 upper die, 13 lower die, 14 intermediate die, 15 mold release film, 16 substrate mounting face, 17 substrate fixing mechanism, 18, 35 adsorbing/fixing portion, 19, 36 holding/fixing portion, 20, 37 ventilable member, 21 chucking pawl, 22 die assembly face closer to upper die, 23 upper storage portion, 24 die assembly face closer to lower die, 25 lower storage portion, 26 cavity, 27 communication channel, 28 chucking pawl storage portion, 29 lower die cavity face, 30 cavity side faces, 31 communication channel face, 32 cavity face, 33 film fixing mechanism, 34, 34a, 34b cavity member, 38 holding member, 39 mounting bar, 40, 44 elastic member, 41 substrate contact portion, 42 receiving member, 43 mount member, 45 upper seal member, 46 lower seal member, 47 upper seal fixing member, 48 lower seal fixing member, 50 die assembly.

### BEST MODES FOR CARRYING OUT THE INVENTION

A method of resin encapsulation molding for electronic parts according to an embodiment of the present invention is now described with reference to FIGS. 1 to 6. In each of the drawings used in the following description, detailed portions are schematically illustrated by omission or exaggeration, in order to simplify the illustration.

As shown in FIG. 1, matrix-type substrates 1 are employed in the method of resin encapsulation molding for electronic parts according to this embodiment. Matrix-type substrates 1 may have any shape such as a circular shape or a polygonal shape. According to this embodiment, substrates 1 have a quadrilateral shape.

A plurality of chips 2 which are examples of a plurality of electronic parts in the present invention are mounted on first main surfaces of substrates 1. Referring to FIG. 1, unencapsulated substrates 3 are drawn on the upper portion of FIG. 1, and encapsulated substrates 10 are drawn on the lower portion of FIG. 1.

Each substrate 1 has an encapsulation-molded portion 6, a substrate periphery 7 and a non-mounted face 8. Encapsulation-molded portion 6 is a portion where chips 2 provided on the first main surface are encapsulated with a resin material 4 (molten resin 5). Substrate periphery 7 is the periphery of encapsulation-molded portion 6 on the first main surface, provided with no resin material 4. Non-mounted face 8 is a second main surface opposed to the first main surface mounted with chips 2.

After chips 2 as electronic parts are encapsulation-molded, encapsulated substrate 10 (product) having cured resin 9 constituting encapsulation-molded portion 6 is formed (refer to the lower portion of FIG. 1).

As shown in FIG. 1, two substrates 1 are mounted on a prescribed position of a die assembly 50 while relatively long end faces thereof are in contact with (adjacent to) each other. According to this structure, the two substrates can be simultaneously compression-molded. Cured resin 11 connecting substrates 1 with each other is molded between encapsulation-molded portions 6 on two substrates 1.

The method of resin encapsulation molding for electronic parts according to the present invention is not only applicable to resin encapsulation molding for the plurality of electronic parts provided on two substrates 1 shown in FIG. 1, but also applicable to resin encapsulation molding for a plurality of electronic parts provided on a plurality of substrates 1.

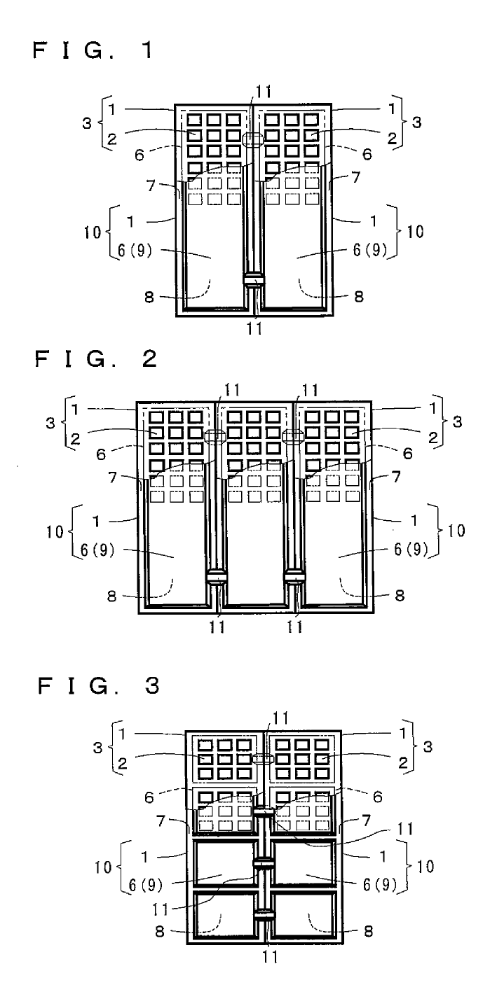

For example, the method of resin encapsulation molding for electronic parts according to the present invention may be applied to resin encapsulation molding for three substrates 1 shown in FIG. 2. Three substrates 1 may be mounted on the upper die while relatively long end faces adjacent to each other are in contact with (adjacent to) each other. Also in this case, encapsulation-molded portions 6 of two adjacent substrates 1 are connected with each other by cured resin 11, similarly to substrates 1 shown in FIG. 1.

Further, the method of resin encapsulation molding for electronic parts according to the present invention may be applied to resin encapsulation molding for a plurality of electronic parts provided on two substrates 1 shown in FIG. 3. In this case, eight encapsulation-molded portions 6 may be formed. Also in this case, a plurality of electronic parts provided on a plurality of (in this case, two) substrates 1 can be substantially simultaneously resin-encapsulated by compression molding. Also in this case, two substrates 1 are connected with each other by cured resin 11 while relatively long end faces adjacent to each other are in contact with (adjacent to) each other.

According to a resin encapsulation molding apparatus of this embodiment, a plurality of electronic parts provided on a plurality of substrates 1 can be substantially simultaneously resin-encapsulated in cured resin 11 by compression molding, without employing complicated clamp means dissimilarly to the prior art. Die assembly 50 of the resin encapsulation molding apparatus according to this embodiment is described later.

As each matrix-type substrate 1, a wire bonding substrate, a flip chip substrate or a wafer level package such as a wafer substrate is employed. As the material for substrate 1, an arbitrary lead frame of metal or plastic referred to as a PC (Printed Circuit) boat, ceramic, glass or another material is employed.

As resin material 4, on the other hand, tablet resin, liquid resin, granular resin, powdered resin, sheet resin or particulate resin smaller than granular resin and larger than powdered resin in diameter is employed.

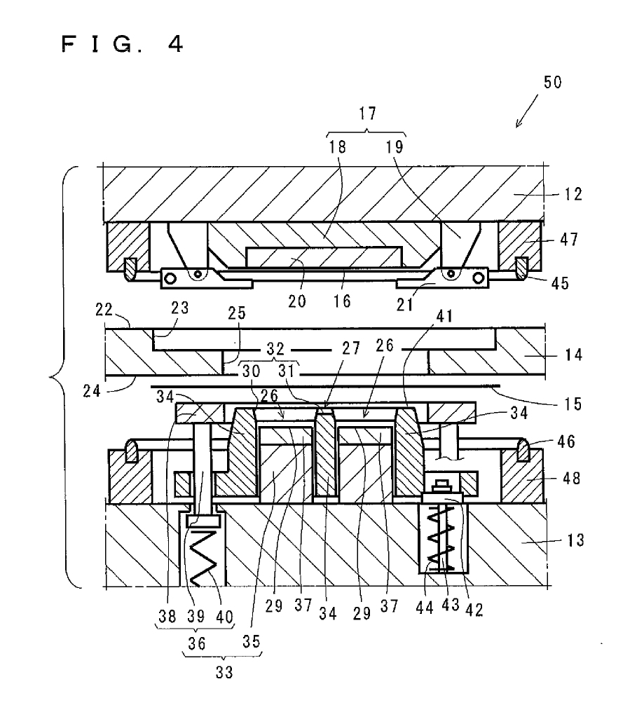

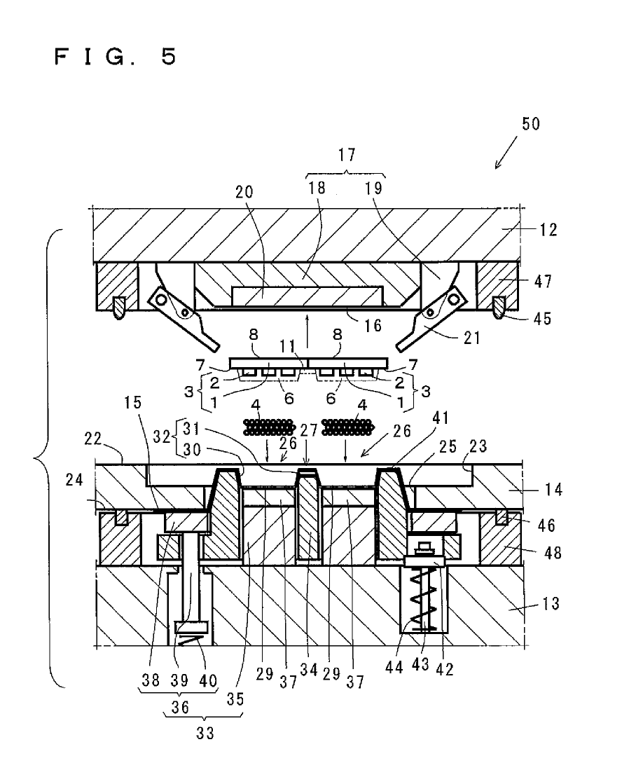

The die assembly according to this embodiment is now described with reference to FIGS. 4 to 8. The die assembly according to this embodiment is employed for substantially simultaneously resin-encapsulating the plurality of electronic parts provided on two substrates 1 shown in any of FIGS. 1 to 3 by compression molding.

Die assembly 50 has a triple die (12-13-14) structure formed by an upper die 12, a lower die 13 opposed to upper die 12 and an intermediate die 14 arranged between upper die 12 and lower die 13. In die assembly 50, a mold release film 15 is employed.

The plurality of electronic parts provided on two unencapsulated substrates 3 shown in FIG. 1 are resin-encapsulated by compression molding. Thus, two encapsulated substrates 10 are formed. Die assembly 50 according to this embodiment is different from the conventional die assembly in the point that the same has not the conventional double die structure but the triple die (12-13-14) structure and the point that mold release film 15 is employed. According to this, encapsulation-molded portions 6 can be efficiently detached from die assembly 50 also in a case of forming encapsulation-molded portions 6 increased in size and reduced in thickness.

Upper die 12 is provided with a substrate fixing mechanism 17, as shown in FIG. 5. Substrate fixing mechanism 17 can fix two unencapsulated substrates 3 to upper die 12 by holding and adsorption on substrate mounting faces 16 of two upper dies 12 while chips 2 of two unencapsulated substrates 3 are directed downward and the relatively long end faces of two substrates 1 are in contact with (adjacent to) each other.

Substrate fixing mechanism 17 includes a substrate adsorbing/fixing portion 18 adsorbing substrates 1 (unencapsulated substrates 3 and encapsulated substrates 10) and a substrate holding/fixing portion 19 for holding substrates 1. This structure is so employed as to more efficiently mount substrates 1 on substrate mounting face 16 correspondingly to the increase in size and the reduction in thickness of substrates 1 in recent years.

Substrate adsorbing/fixing portion 18 has a substrate ventilable member 20 and an evacuation mechanism (not shown). Substrate ventilable member 20 is made of a material such as metal or ceramic having air permeability and heat resistance, in order to adsorb non-mounted faces 8 of substrates 1. The evacuation mechanism is provided on the upper face of ventilable member 20 opposed to the lower face (substrate mounting face 16), for forcibly sucking air, moisture and gases from a channel communicating with ventilable member 20 through a pipe and a valve. According to this, two matrix-type substrates 1 are adsorbed to substrate ventilable member 20 due to the action of the evacuation mechanism. The evacuation mechanism may be employed for spraying air to non-mounted faces 8 of two encapsulated substrates 10 through the aforementioned channel communicating with ventilable member 20 substantially at the same time when two encapsulated substrates 10 are released from substrate holding/fixing portion 19.

Substrate holding/fixing portion 19 includes chucking pawls 21 (on 10 portions in this case) provided around substrate adsorbing/fixing portion 18, in order to hold substrate peripheries 7 of two substrates 1. Chucking pawls 21 may also be provided on the position between two substrates 1. In general, chucking pawls 21 substantially horizontally extend in a state not in contact with substrate mounting face 16. When substrates 1 (3-10) are mounted on substrate fixing mechanism 17 or detached from substrate fixing mechanism 17, chucking pawls 21 are converted from the horizontally extending state (closed state) to a state (open state) where the forward ends thereof rotate toward the upper face of intermediate die 14, as shown in FIG. 5.

As hereinabove described, the resin encapsulation molding apparatus according to this embodiment can execute both of adsorption of substrate adsorbing/fixing portion 18 and holding of substrate holding/fixing portion 19. Therefore, various substrates 1 can be reliably mounted on substrate mounting face 16 of upper die 12. More specifically, two substrates 1 are prevented from downward and horizontal deviation.

Intermediate die 14 has a die assembly face 22 opposed to upper die 12 and another die assembly face 24 opposed to lower die 13, as shown in FIG. 4. Intermediate die 14 further has an upper storage portion 23 having an opening in upper die assembly face 22 closer to the upper die and a lower storage portion 25 having an opening in die assembly face 24 closer to the lower die. Upper storage portion 23 and lower storage portion 25 communicate with each other, to constitute vertically extending penetration. When upper die 12 and intermediate die 14 are closed, chucking pawls 21 are stored in upper storage portion 23 and lower storage portion 25, not to come into contact with intermediate die 14. At this time, cavities 26 of lower die 13 reach upper storage portion 23 through lower storage portion 25. Mold release film 14 is inserted between die assembly face 24 of intermediate die 14 closer to the lower die and the upper face of lower die 13 in a tensioned state when die assembly 50 is opened, as shown in FIG. 4.

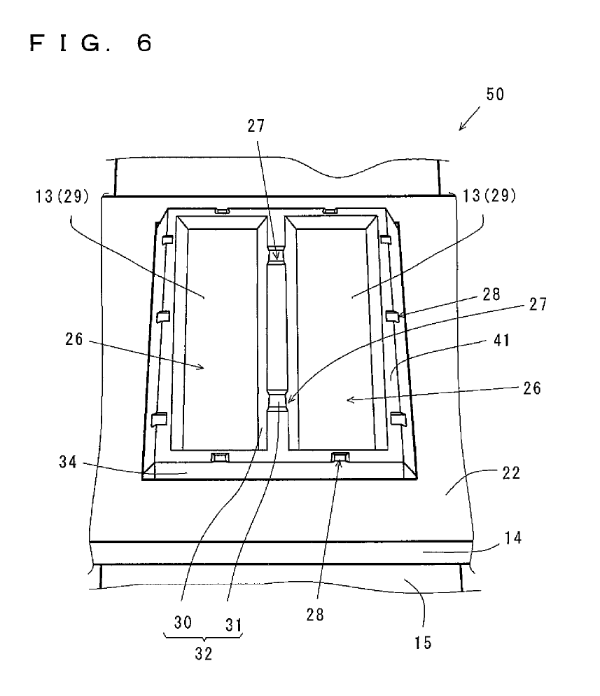

Lower die 13 includes cavities 26 having shapes corresponding to encapsulation-molded portions 6 (cured resin 9) of two substrates 1, as shown in FIG. 6. FIG. 6 illustrates no upper die 12. Intermediate die 14 and lower die 13 are so closed that mold release film 15 covers communication channels 27 making cavities 26 communicate with each other, as shown in FIG. 6. Mold release film 15 also covers a chucking pawl storage portion 28 so provided on upper die 12 as to store chucking pawls 21 when upper die 12, intermediate die 14 and lower die 13 are closed. Cavities 26 have shapes corresponding to two encapsulation-molded portions 6 shown in FIG. 1. More specifically, lower die cavity faces 29 of lower die 13 have shapes corresponding to the upper faces of encapsulation-molded portions 6.

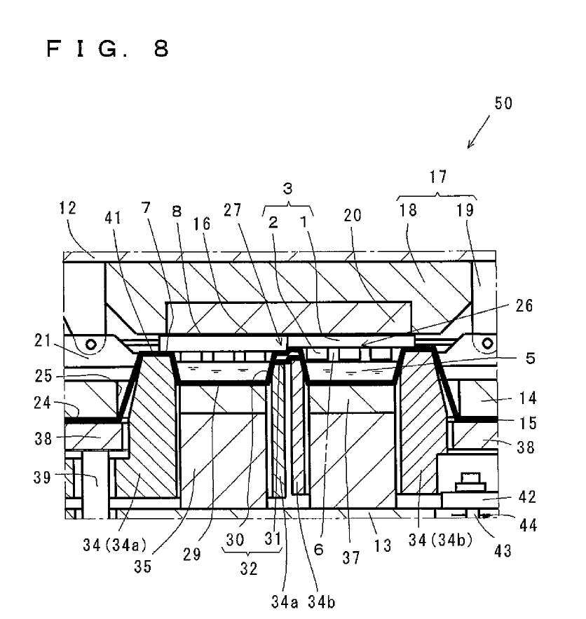

As shown in FIG. 4, cavities 26 include cavity faces 32, in addition to lower die cavity faces 29. Cavity faces 32 include cavity side faces 30 enclosing the peripheries of lower die cavity faces 29 and communication channel faces 31 (two portions in this case) forming communication channels 27 making cavities 26 communicate with each other. Lower die 13 further includes a film fixing mechanism 33 holding mold release film 15 in association with intermediate die 14 and adsorbing mold release film 15 to cavities 26 and a cavity member 34 defining cavity faces 32 (cavity side faces 30 and communication channel faces 31). As shown in FIGS. 4 to 7, cavity member 34 has an integral structure, and is employed when the thicknesses of two substrates 1 are substantially identical to each other. When the thicknesses of two substrates 1 are different from each other, on the other hand, another cavity member 34 having a separate structure is preferably employed, as shown in FIG. 8. The separate structure is formed by a cavity member 34a corresponding to one of two substrates 1 and another cavity member 34b corresponding to the other one of two substrates 1. When the separated structure of cavity member 34 is employed in this manner, mass production of products having different thicknesses of substrates 1 can be implemented.

Film fixing mechanism 33 includes a film adsorbing/fixing portion 35 adsorbing mold release film 15 and a film holding/fixing portion 36 holding mold release film 15. According to this structure, mole release film 15 can be brought into close contact with the overall faces of cavities 26 along the overall faces of cavities 26 even if substrates 1 have small thicknesses.

Film adsorbing/fixing portion 35 includes film ventilable members 37 and an evacuation mechanism (not shown). Film ventilable members 37 are made of a material such as metal or ceramic having air permeability and heat resistance, so that mold release film 15 can be adsorbed to lower die cavity faces 29. The evacuation mechanism discharges air, moisture and gases by forcible suction through the lower face opposed to lower die cavity faces 29 forming the upper faces of ventilable members 37, a communication channel communicating with ventilable members 37, a pipe and a valve. While lower die cavity faces 29 and film ventilable members 37 are provided correspondingly to the respective ones of two substrates 1, the evacuation mechanism may be formed by one mechanism.

Air can be sprayed from lower die cavity faces 29 to encapsulation-molded portions 6, so that cured encapsulation-molded portions 6 (cured resin 9) separate from mold release film 15 through the aforementioned channel.

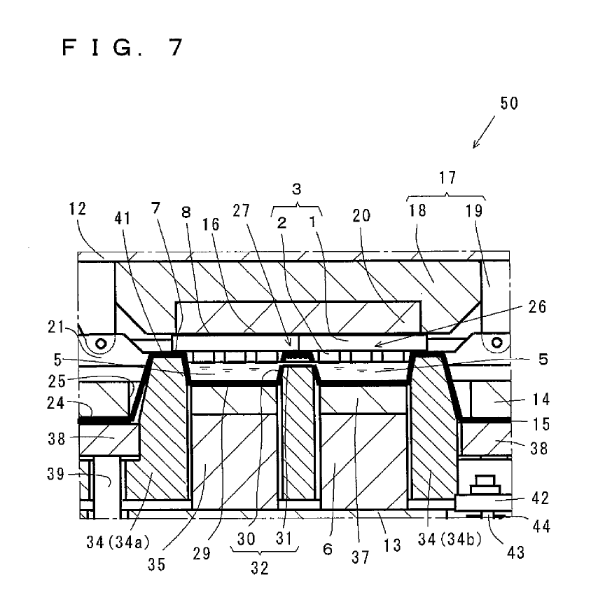

Film holding/fixing portion 36 includes cavity member 34. Cavity member 34 is so provided around film adsorbing/fixing portion 35 as to enclose film adsorbing/fixing portion 35 in plan view. Film holding/fixing portion 36 further includes a holding member 38 for holding mold release film 15, a plurality of mounting bars 39 so mounted on the lower face of holding member 38 as to vertically extend and an elastic member 40 formed by a spring or the like elastically supporting holding member 38 and mounting bars 39. When die assembly 50 is opened, elastic member 40 is restored (expands) so that the upper face of holding member 38 is located upward beyond lower die 13, as shown in FIG. 4. When holding member 38 and mounting bars 39 move downward while intermediate die 14 and lower die 13 are fitted with each other, on the other hand, elastic member 40 shrinks. Lower die 13 further moves upward. Thus, die assembly 50 is completely closed, as shown in FIG. 7. In this state, elastic member 40 most shrinks.

Cavity member 34 is fitted around adsorbing/fixing portion 35 of film fixing mechanism 33, as understood from FIG. 4. Cavity member 34 has a sectional shape consisting of a vertical portion and a horizontal portion, which form a L-shape. As hereinabove described, cavity member 34 may have an integral structure, as shown in FIGS. 4 to 7. Alternatively, cavity member 34 may have a separable structure provided with cavity members 34a and 34b, as shown in FIG. 8.

The vertical portions of cavity member 34 include cavity side faces 30 and substrate contact portions 41 pressing substrate peripheries 7 of two substrates 1, as shown in FIG. 6. Two communication channels 27 for resin control are provided on the upper portions of cavity side faces 30. Communication channels 27 are provided between two cavities 26. The respective ones of two communication channels 27 make two cavities 26 communicate with each other. Therefore, molten resin 5 is uniformly distributed into two cavities 26. The vertical portions of cavity member 34 are provided with chucking pawl storage portions 28. When die assembly 50 is closed, chucking pawl storage portions 28 store the forward ends of chucking pawls 21, so that chucking pawls 21 and substrate contact portions 41 do not come into contact with each other.

As shown in FIGS. 4 to 6, cavity member 34 includes chucking pawl storage portions 28, substrate contact portions 41 excluding chucking pawl storage portions 28, communication channel faces 31 and cavity side faces 30 excluding communication channel faces 31. When cavity member 34 is separated into one cavity member 34a and the other cavity member 34b as shown in FIG. 8, on the other hand, each of one cavity member 34a and the other cavity member 34b includes chucking pawl storage portions 28, substrate contact portions 41 excluding chucking pawl storage portions 28, communication channel faces 31 and cavity side faces 30 excluding communication channel faces 31, as shown in FIG. 8.

Lower die 13 includes a receiving member 42 receiving the horizontal portion forming L-shaped cavity member 34, a mount member 43 mounted on receiving member 42 and an elastic member 44 such as a spring enclosing mount member 43. In the open state shown in FIG. 4, cavity side faces 30 of cavity member 34 are located upward beyond the respective ones of lower die cavity faces 29 corresponding two substrates 2 and downward beyond the upper face of holding member 38. At this time, elastic member 44 is in a restored (expanding) state. When lower die 13 moves upward from the open state shown in FIG. 4, die assembly 50 enters a closed state. At this time, cavity member 34 comes into contact with the upper face of lower die 13, and elastic member 44 most shrinks.

When the respective ones of two lower die cavity faces 29 are covered with mold release film 15, intermediate die 14 and lower die 13 are converted to the closed state shown in FIGS. 5 and 6 from the open state of die assembly 50 shown in FIG. 4. Thus, mold release film 15 is held by film holding/fixing portion 36. At this time, mold release film 15 is forcibly sucked by film adsorbing/fixing portion 35 toward lower die cavity faces 29. Thus, mold release film 15 covers the overall faces of cavities 26, i.e., the overall faces of lower die cavity faces 29, cavity side faces 30 and communication channel faces 31 in a tensioned state.

FIG. 5 shows cavities 26 whose die faces are in close contact with tensioned mold release film 15. This state is a state immediately before resin material 4 (granular resin in this case) is supplied into cavities 26. In general, it is difficult to uniformly supply resin material 4 into two cavities 26. Therefore, the resin capsulation molding apparatus according to this embodiment is provided with communication channels 27 making cavities 26 communicate with each other. According to this, resin material 4 is not uniformly supplied into two cavities 26 when die assembly 50 is opened as shown in FIG. 5, while the same is uniformly distributed into two cavities 26 through communication channels 27 when die assembly 50 is closed as shown in FIG. 7. This function is not restricted to the case of employing substrates 1 shown in FIG. 1, but can take place also when substrates 1 shown in FIGS. 2 and 3 are employed.

Thereafter a time necessary for curing molten resin 5 elapses while die assembly 50 is completely closed. Thus, molten resin 5 is converted to cured resin 9. Two encapsulated substrates 10 shown in FIG. 1 are substantially simultaneously formed by compression molding. While molten resin 5 may be formed by heating solid resin in cavities 26, molten resin 5 formed in a pot or the like may be injected into cavities 26. Further, liquid resin may be externally injected into cavities 26 in place of molten resin 5.

Degating means (not shown) may be so employed as to cut cured resin 11 in the communication channels inside or outside die assembly 50 before a singulation step. Thus, one encapsulated substrate is completed. Alternatively, cured resin 11 in the communication channels may be cut with a singulation apparatus.

Further, an upper seal member 45 coming into contact with die assembly face 22 of intermediate die 14 closer to the upper die and a lower seal member 46 coming into contact with die assembly face 24 of intermediate die 14 closer to the lower die are provided on the die faces of upper die 12 and lower die 13 respectively. Upper seal member 45 and lower seal member 46 are so employed as to maintain the degree of vacuum in the space of die assembly 50 according to this embodiment when the evacuation mechanism (not shown) is used.

While upper seal member 45 and lower seal member 46 are mounted on upper die 12 and lower die 13 respectively in this embodiment, a structure employing only upper seal member 45 on upper die 12 may alternatively be employed. Upper seal member 45 and lower seal member 46 are mounted on an upper seal fixing portion 47 and a lower seal fixing portion 48 provided outward beyond substrate fixing mechanism 17 and film fixing mechanism 33 in protruding states respectively. As the material for each of upper seal member 45 and lower seal member 46, a material such as a hollow seal or an O-ring excellent in elasticity, heat resistance and durability is employed. In an evacuation step, die assembly face 22 of intermediate die 14 closer to the upper die comes into contact with upper seal member 45, thereby crushing upper seal member 45. While a space isolated from the outside air is thereafter formed by upper die 12, intermediate die 14 and lower die 13, moisture and gases as well as air in this space are discharged by forcible suction through the pipe and the valve.

Thus, the plurality of electronic parts provided on two substrates 1 can be substantially simultaneously resin-encapsulated by compression molding without forming voids or the like by employing both of mold release film 15 and evacuation.

The method of resin encapsulation according to this embodiment is now described stepwise.

First, mold release film 15 is inserted between the upper face of holding member 38 of film holding/fixing portion 36 and die assembly face 24 of intermediate die 14 closer to the lower die in a substantially horizontally extending and tensioned state in the state where upper die 12, lower die 13 and intermediate die 14 are opened, as shown in FIG. 4. On substrate holding/fixing portion 19 of upper die 12, on the other hand, chucking pawls 21 wait in a substantially horizontally extending state.

Then, mold release film 15 comes into contact with die assembly face 24 of intermediate die 14 closer to the lower die. In this state, intermediate die 14 moves downward. Thus, intermediate die 14 moves downward while mold release 15 is held by die assembly face 24 closer to the lower die and the upper face of holding member 38. At this time, mounting bars 39 of holding/fixing portion 36 also move downward. Thus, elastic member 40 shrinks.

Then, intermediate die 14 and holding member 38 integrally move downward while mold release film 15 is held by intermediate die 14 and holding member 38 of lower die 13. Thus, the lower face of holding member 38 and the upper face of the horizontal portion of cavity member 34 come into contact with each other. Substantially at the same time, mold release film 15 is forcibly sucked by adsorbing/fixing portion 35 of film fixing mechanism 33 toward lower die cavity faces 29 in the tensioned state in upper storage portion 23 and lower storage portion 25 of intermediate die 14, i.e., in substrate contact portions 41. At this time, substrate contact portions 41 of the vertical portions of L-shaped cavity member 34 are stored in upper storage portion 23 and lower storage portion 25 of intermediate die 14. Further, mold release film 15 in substrate contact portions 41 protrudes upward beyond the upper face of intermediate die 14. Mold release film 15 is held by intermediate die 14 and holding member 38. Further, overall die assembly 50 is heated for melting resin material 4. Therefore, mold release film 15 comes into close contact with cavities 26 in substrate contact portions 41.

Thereafter mold release film 15 is continuously forcibly sucked toward lower die cavity faces 29 in the state tensioned in substrate contact portions 41. Thus, mold release film 15 covers cavities 26 along the shapes of the overall faces of cavities 26 including lower die cavity faces 29 and cavity faces 32 (cavity side faces 30 and communication channel faces 31), as shown in FIGS. 5 and 6. Thus, the state shown in FIGS. 5 and 6 is formed. In this state, two cavities 26 are so formed as to correspond to encapsulation-molded portions 6 of the aforementioned two substrates 1 respectively.

Then, a preparation step for supplying resin material 4 into cavities 26 is executed, as shown in FIG. 5. In upper die 12, on the other hand, the forward ends of chucking pawls 21 so rotate as to separate from substrate mounting face 16 of upper die 12 not to come into contact with two substrates 1 when two unencapsulated substrates 3 are mounted.

Then, resin material 4 is supplied into cavities 26. At this time, resin material 4 is converted to molten resin 5 when die assembly 50 is closed as shown in FIG. 6 as described later. At this time, molten resin 5 is uniformly distributed into two cavities 26 through communication channels 27. Therefore, the quantities of resin material 4 may slightly vary when supplied into two cavities 26.

Then, another preparation step for moving intermediate die 14 and lower die 13 toward upper die 12 is executed. At this time, substrate peripheries 7 of two unencapsulated substrates 3 are held by chucking pawls 21 while non-mounted faces 8 of two unencapsulated substrates 3 are adsorbed to substrate mounting face 16 of upper die 12. Thus, two unencapsulated substrates 3 are reliably fixed to upper die 12 by substrate fixing mechanism 17. At this time, overall die assembly 50 is heated to a temperature necessary for melting resin material 4. Therefore, resin material 4 is converted to molten resin 5 in cavities 26. Mold release film 15 covers cavities 26, and is in close contact with cavities 26 along the shapes of the overall faces of cavities 26 without causing film wrinkles because of the own weight of molten resin 5.

If the steps of mounting two unencapsulated substrates 3 on the die face of upper die 12 and forming closed spaces in cavities 26, preheating overall die assembly 50 and supplying resin material 4 into cavities 26 are carried out before the evacuation step described later, the order of these steps may be changed.

Then, intermediate die 14 and lower die 13 integrally move upward toward upper die 12 while molten resin 5 is present in cavities 26. Thus, die assembly 50 enters an intermediately closed state. At this time, die assembly face 22 of intermediate die 14 closer to the upper die is in contact with upper seal member 45 formed on the die face of upper die 12. Therefore, upper seal member 45 is in a crushed state. In this state, a space isolated from the outside air is formed in die assembly 50. Substantially at the same time, air and the like are forcibly discharged by suction through the channel communicating with the evacuation mechanism. This is referred to as the evacuation step. Resin material 4 supplied into cavities 26 may not be converted to molten resin 5 in the aforementioned intermediately closed state, but may be converted to molten resin 5 before the evacuation is stopped.

While the evacuation step of this embodiment is executed in the aforementioned intermediately closed state, this step may alternatively be intermittently executed while the intermediately closed state and the completely closed state are repeated, or may be continuously executed without stopping the movement of die assembly 50 in the period for shifting from the intermediately closed state to the completely closed state while die assembly 50 moves at a closing speed (traveling speed of die assembly 50) slower than the preceding speed.

When intermediate die 14 and lower die 13 further integrally move upward, the die face of upper die 12 and die assembly face 22 of intermediate die 14 closer to the upper die come into contact with each other, as shown in FIG. 7. At this time, substrate contact portions 41 in cavities 26 substantially simultaneously come into contact with substrate peripheries 7 of two unencapsulated substrates 3 while holding mold release film 15 therebetween. At this time, the electronic parts (chips 2) are dipped in molten resin 5 in cavities 26. Chucking pawls 21 are stored in upper storage portion 23 of intermediate die 14 and chucking pawl storage portion 28 of cavity member 34 while holding substrate peripheries 7 of two unencapsulated substrates 3.

Thus, substrate peripheries 7 of two unencapsulated substrates 3 are clamped by substrate contact portions 41 and upper die 12. Therefore, molten resin 5 is prevented from leaking onto substrates 1 of two substrate peripheries 7, although compression molding is executed in die assembly 50.

While die assembly face 22 of intermediate die 14 closer to the upper die is in contact with the die face of upper die 12 in this embodiment, the die face of upper die 12 and die assembly face 22 closer to the upper die may alternatively separate from each other so far as upper seal member 45 is completely crushed and the space in die assembly 50 is isolated from the outside air. The evacuation step may be stopped at any timing in the period for shifting from the intermediately closed state to the completely closed state. However, the evacuation step is preferably continued up to completion of resin encapsulation and stopped after completion of resin encapsulation.

While cavity member 34 has the integral structure in this embodiment as shown in FIG. 7, cavity member 34 may alternatively have the separated structure consisting of two cavity members 34a and 34b corresponding to the respective ones of two substrates 1, as shown in FIG. 8. The timing when cavity member 34a comes into contact with substrate 1 and the timing when cavity member 34b comes into contact with substrate 1 are different from each other due to the difference in thickness between two substrates 1. However, cavity member 34a and cavity member 34b can move to different positions in response to the thicknesses of the respective ones of two substrates 1 respectively. Therefore, both of substrate contact portion 41 of cavity member 34a and substrate contact portion 41 of cavity member 34b can firmly press substrate peripheries 7 of two substrates 1.

When lower die 13 further moves upward while intermediate die 14 and lower die 13 are in contact with each other, two electronic parts (chips 2) are substantially simultaneously resin-encapsulated by compression molding. At this time, the lower face of cavity member 34 moves downward and comes into contact with the upper face of lower die 13 while holding member 38 and cavity member 34 are in contact with each other. Further, the respective ones of elastic members 40 and 44 provided on lower die 13 most shrink. This state is the completely closed state of die assembly 50 (three dies 12, 13 and 14).

Communication channels 27 making substrates 1 communicate with each other are so provided that molten resin 5 is uniformly distributed into two cavities 26 in the state where die assembly 50 according to this embodiment is closed. However, also when lower die 13 has such a structure that the vertical positions of lower die cavity faces 29 are changeable in place of communication channels 27, molten resin 5 is uniformly distributed into two cavities 26. A measuring apparatus (not shown) such as a pressure sensor may be provided in die assembly 50, so that the closing pressure can be monitored.

After the time necessary for curing molten resin 5 elapses while the completely closed state of die assembly 50 is maintained, encapsulation-molded portions 6 including two chips 2, i.e., cured resin 9 is molded. Thus, two encapsulated substrates 10 (products) are completed. While both of substrate fixing mechanism 17 and film fixing mechanism 33 continue the suction with the evacuation mechanism at this time, the suction of either one or both thereof with the evacuation mechanism may be stopped.

Then, intermediate die 14 and lower die 13 are opened, in order to separate completed two encapsulated substrates 10 from mold release film 15. In other words, only lower die 13 (lower die cavity faces 29) moves downward from the state shown in FIG. 7. Thus, clearances are formed between mold release film 15 covering cured resin 9 of the respective ones of two substrates 1 and the respective ones of two lower die cavity faces 29. Substantially at the same time, air is blown from the respective ones of two lower die cavity faces 29 due to the action of the evacuation mechanism connected to adsorbing/fixing portion 35 of film fixing mechanism 33. Thus, air is sprayed from the respective ones of two lower die cavity faces 29 to the respective ones of encapsulation-molded portions 6 (9) of two encapsulated substrates 10 through mold release film 15.

Then, intermediate die 14 and lower die 13 are further separated from upper die 12 white two encapsulated substrates 10 separate from the respective ones of corresponding two lower die cavity faces 29. At this time, two encapsulated substrates 10 are mounted on substrate mounting faces 16 of upper die 12. Intermediate die 14 and lower die 13 integrally move downward.

In order to detach two encapsulated substrates 10 from die assembly 50, chucking pawls 21 so rotate that the forward ends thereof separate from substrate mounting faces 16 of upper die 12 and enter open states substantially at the same time with the state of die assembly 50 shown in FIG. 5. Thus, two encapsulated substrates 10 are substantially simultaneously detached from substrate mounting faces 16 of upper die 12.

While the series of resin encapsulation molding steps by compression molding have been described with reference to FIGS. 4 to 8 as two unencapsulated substrates 3 are substantially simultaneously converted to two encapsulated substrates 10, these series of resin encapsulation steps may be executed either in a continuous mode or in an intermittent mode.

According to the method of resin encapsulation molding for electronic parts (chips 2) of this embodiment, mold release film 15 is so employed that mold releasability of resin material 4 (including high-density resin material 4) and die assembly 50 is remarkably improved. Further, the evacuation mechanism is so employed as to prevent voids (bubbles) from remaining in resin material 4. In addition, compression molding is so employed that a large number of thin chips 2 mounted on matrix-type substrates 1 can be substantially simultaneously resin-encapsulated.

While the present invention has been described in detail, this is only for illustration and must not be taken as restriction, and it will be clearly understood that the range of the invention is limited by only the accompanying scope of claims for patent.

1-4. (canceled)

5. A method of resin encapsulation molding for electronic parts, comprising the steps of:
preparing a die assembly including an upper die, a lower die opposed to said upper die and provided with a plurality of cavities and an intermediate die provided between said upper die and the lower die and a mold release film;
mounting a plurality of substrates mounted with electronic parts respectively on said upper die;
bringing said mold release film into close contact with said plurality of cavities by said intermediate die and said lower die;
closing said die assembly while said plurality of cavities are covered with the mold release film;
forming molten resin in said plurality of cavities, or injecting liquid resin or molten resin into said plurality of cavities; and
substantially simultaneously dipping said plurality of electronic parts in said liquid resin or molten resin so that said liquid resin or molten resin is uniformly distributed in said plurality of cavities through a communication channel making said plurality of cavities communicate with each other while said die assembly is closed.

6. The method of resin encapsulation molding for electronic parts according to claim 5, wherein
the respective ones of said plurality of cavities include lower die cavity faces serving as the bottom faces thereof and cavity side faces adjacent to said lower die cavity faces, and
said cavity side faces and said lower die cavity faces are separable.

7. The method of resin encapsulation molding for electronic parts according to claim 5, wherein
said plurality of substrates are mounted on said upper die while said plurality of substrates are adjacent to each other in the step of mounting said plurality of substrates.

8. The method of resin encapsulation molding for electronic parts according to claim 5, wherein
the clearance between said upper die and said intermediate die is sealed with a seal member for cutting off the outside air in the closing step,
said method of resin encapsulation molding further comprising the step of evacuating the spaces in said cavities after the closing step.
